(19) United States
(12) Patent Application Publication
(10) Pub. No.: US 2024/0006380 A1
(43) Pub. Date: Jan. 4, 2024

(54) METALLIZATION SURFACE TREATMENT FOR INTEGRATED CIRCUIT PACKAGES

(71) Applicant: Intel Corporation, Santa Clara, CA (US)

(72) Inventors: Suddhasattwa Nad, Chandler, AZ (US); Srinivas Pietambaram, Chandler, AZ (US); Rahul Manepalli, Chandler, AZ (US); Marcel Wall, Phoenix, AZ (US); Darko Grujicic, Chandler, AZ (US)

(73) Assignee: Intel Corporation, Santa Clara, CA (US)

(21) Appl. No.: 17/856,830

(22) Filed: Jul. 1, 2022

(51) Int. Cl. H01L 25/065; H01L 23/538; H01L 23/498; H01L 21/48

(52) U.S. Cl. CPC H01L 25/0655; H01L 23/5383; H01L 23/49866; H01L 21/4857

(57) ABSTRACT

High-density IC die package routing structures with one or more nitrided surfaces. Metallization features may be formed, for example with a plating process. Following the plating process, a surface of the metallization features may be exposed to a surface treatment that incorporates nitrogen onto a surface of the metallization. The presence of nitrogen may chemically improve adhesion between finely patterned metallization features and package dielectric material. Accordingly, surface roughness of metallization features may be reduced without suffering delamination. With lower surface roughness, metallization features may transmit higher frequency data signals with lower insertion loss.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical contacts suitable for further connecting to a host component, such as a printed circuit board (PCB). In the IC industry, the process of fabricating a package is often referred to as packaging, or assembly.

Next generation multi-chip packaging (MCP) demands greater interconnect density to support evolving systems-in-package and/or bandwidth-intensive applications. In a high bandwidth architecture, for example, multiple IC dies assembled on a package may need to be electrically interconnected through fine routing layers that include lines (i.e., traces) embedded within an interconnect level of the package at a density of at least 250 trace/mm Higher speed I/O data transfer is also important for next generation interconnects (e.g., SERDES) that are to exceed 28 GHz. Such interconnects need to operate with low signal losses. At higher frequencies, signal transfer becomes more sensitive to the surface of the interconnect metallization features (e.g., lines or traces), known as the “skin effect.” For example, at a 1 MHz signal transmission frequency, skin depth is about 66 μm. However, at 28 GHz the skin depth is only ˜400 nm.

For package substrates that are typically fabricated through semi-additive techniques, the need for greater interconnect trace density compounded with the need to reduce trace roughness is demanding new approaches and/or architectures to replace conventions that have proven limited to lower line metallization densities and signal transmission frequencies.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIG. 1 is a flow diagram illustrating methods of fabricating IC device package routing with metallization features comprising a nitride surface, in accordance with some embodiments;

FIGS. 2, 3, 4, 5, 6 and 7 illustrate cross-sectional views through an IC device package as selected operations of an IC device package fabrication process is performed, in accordance with some embodiments;

FIG. 8 is a flow diagram illustrating methods of fabricating IC device package routing with metallization features comprising a nitride surface, in accordance with some alternative embodiments;

FIGS. 9, 10, 11, 12 and 13 illustrate cross-sectional views through an IC device package as selected operations of an IC device package fabrication process is performed, in accordance with some alternative embodiments;

FIG. 14 illustrates a system including an IC device package interconnecting two IC die, in accordance with some embodiments;

FIG. 15 illustrates a mobile computing platform and a data server machine employing package routing with nitrided metallization features, in accordance with embodiments; and

FIG. 16 is a functional block diagram of an electronic computing device, in accordance with some embodiments.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

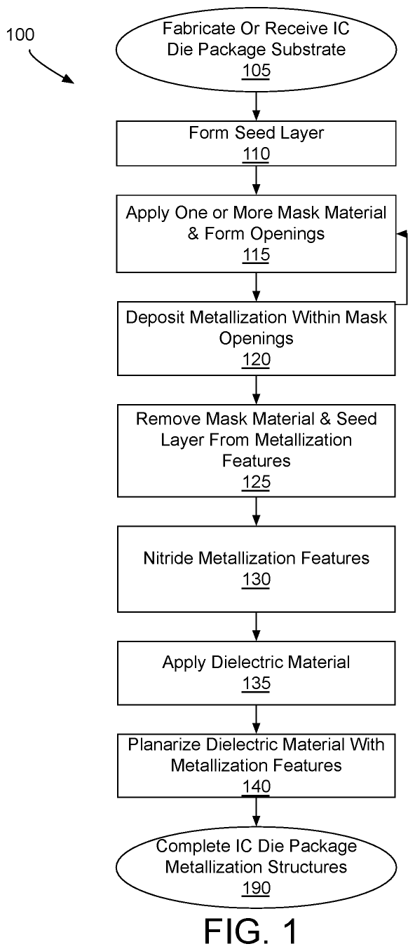

FIG. 1 is a flow diagram illustrating methods 100 for fabricating IC device package \with metallization features comprising a metal nitride surface layer, in accordance with some embodiments. Methods 100 are generally semi-additive processing (SAP) techniques. According to some embodiments, nitrided metallization features may comprise lines or traces that interconnect two IC die assembled with the package and may be electrically insulated with one or more organic dielectric build-up materials that adhere well to the chemically treated surfaces of the metallization. With their metal nitride surface layers, line metallization fabricated according to methods 100 may transmit high-frequency data signals with greater integrity as the surface of the metallization features can be significantly smoother without suffering delamination of the insulator. Accordingly, the IC device package metallization methods 100 may be advantageous for 2D, 2.5D, and 3D MCP packages.

Generally, the package line metallization structures fabricated according to methods 100 may chemically enhance adhesion between the metallization and package insulator material(s) so that package line metallization need not be mechanically treated to avoid delamination of the package insulator. Because mechanical treatments generally rely to some extent on micro-roughening of the metallization feature surfaces, the chemical adhesion treatments described herein induce less dimensional loss and can reduce the average roughness of the metallization features. Signals conveyed through the line metallization fabricated according to methods 100 may therefore experience lower insertion losses.

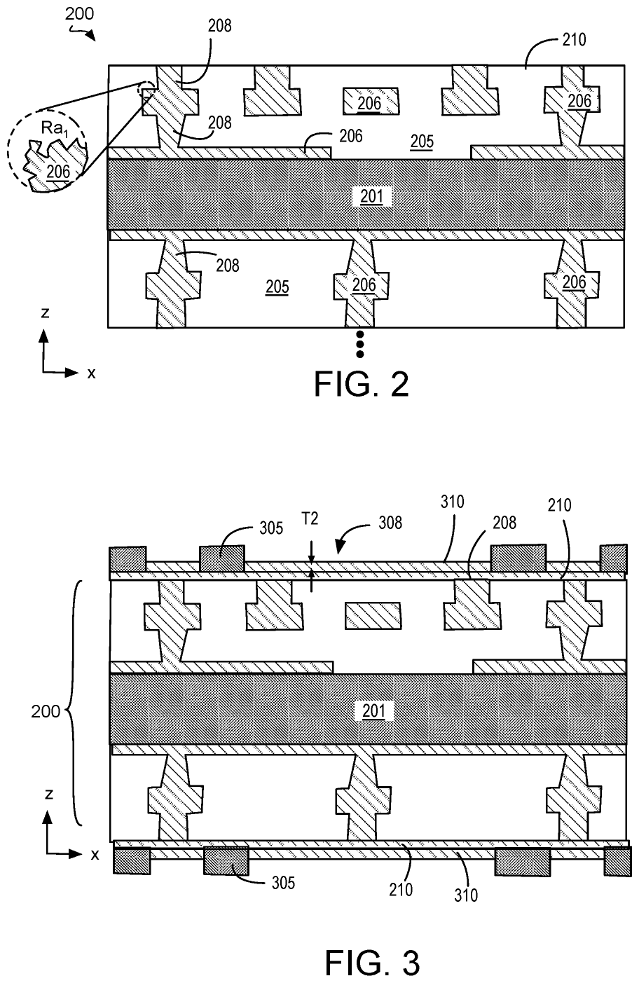

Methods 100 may be repeated any number of times to build up an interconnect structure comprising any number of levels of metallization features comprising multiple material layers. FIGS. 2-7 illustrate cross-sectional views through an IC device package as selected operations of one iteration of methods 100 are performed, in accordance with some embodiments. In FIGS. 2-7 exemplary metallization structures are illustrated on a “die-side” and on a “land-side” of the IC device package. However, processing may instead be distinguished between sides of an IC device package.

Referring first to FIG. 1, methods 100 begin at input 105 where a workpiece including a package substrate suitable for SAP is either fabricated or received as a preform. The package substrate fabricated or received at input 105 may have any architecture as embodiments are not limited in this context. Generally, the package substrate includes at least some electrically insulative material (i.e., insulator), and may further include one or more metallization features embedded within the insulator. In some embodiments, the workpiece fabricated or received is substantially planar and dimensioned in thickness and lateral area to be a suitable support for panelized processing of multiple packages arrayed over the substrate (i.e., WLP). As further described below, the substrate may comprise one or more material layers. The various material layers of a substrate may be retained within a final singulated package, or separated from a final package as part of a sacrificial carrier.

The package substrate fabricated or received at input 105 may be “cored” or “coreless.” In the absence of a core, a package substrate may rely on a sacrificial carrier to mechanically support the package build-up materials. In the example further illustrated in FIG. 2, package substrate 200 comprises a “core” 201. Core 201 may be any preform comprising any material with mechanical rigidity and/or stiffness sufficient to serve as a platform for building up layers of package metallization comprising line metallization 206 and via metallization 208 between two levels of line metallization 206. Such a build-up may be performed concurrently on a front (die) side and a back (land) side of the core 201.

As further illustrated in FIG. 2, package metallization is embedded within one or more layers of package insulator 205. In exemplary embodiments, package insulator 205 comprises an organic dielectric material (e.g., comprising a polymer). Package insulator 205 may comprise an epoxy resin, phenolic-glass, or a resinous film such as the GX-series films commercially available from Ajinomoto Fine-Techno Co., Inc.). Exemplary epoxy resins include an acrylate of novolac such as epoxy phenol novolacs (EPN), or epoxy cresol novolacs (ECN). In some specific examples, package insulator 205 is a bisphenol-A epoxy resin, for example including epichlorohydrin. In other examples, package insulator 205 includes bisphenol-F epoxy resin (with epichlorohydrin). In other examples, package insulator 205 includes aliphatic epoxy resin, which may be monofunctional (e.g., dodecanol glycidyl ether), difunctional (butanediol diglycidyl ether), or have higher functionality (e.g. trimethylolpropane triglycidyl ether). In still other examples, package insulator 205 includes glycidylamine epoxy resin, such as triglycidyl-p-aminophenol (functionality 3) and N,N,N′,N′-tetraglycidyl-bis-(4-aminophenyl)-methane (functionality 4). Although such polymeric materials may decompose at high processing temperatures (e.g., >400° C.), these materials may offer many advantages associated with SAP techniques.

Line and via metallization 206, 208 may have been formed with an additive or semi-additive process, for example. In some embodiments, line and via metallization 206, 208 comprise one or more layers of predominantly copper. For example, line metallization 206 may include a first layer of Cu that may have been deposited with a first deposition process (e.g., electroless plating), and a second layer of Cu that may have been deposited with a second deposition process (e.g., electrolytic plating) that relied on the first layer of Cu functioning as a seed layer. Since such material layers are both predominantly Cu, separate layers are not illustrated in FIG. 2. However, differences in the deposition process may result in the two layers having a different microstructure and/or impurity concentration. In accordance with SAP processing techniques, a blanket seed layer is patterned after depositing all line metallization. Since both the seed layer and overlayer are predominantly Cu, line metallization 206 may experience dimensional loss (e.g., >2 μm) during the seed layer patterning and/or other processing performed in preparation for depositing a layer of insulator upon exposed surfaces of line metallization 206. In the expanded view of FIG. 2, significant roughness (e.g., Ra₁>>100 nm) is illustrated on at least a top surface of in line metallization 206. For exemplary embodiments where line metallization 206 is not to convey high frequency (e.g., exceeding 1 GHz) data signals, but is instead power routing, etc., such surface roughness need not be detrimental to IC device package performance.

Returning to FIG. 1, methods 100 continue with the fabrication of a package routing structure that includes one or more nitrogen treated (i.e., nitrided) metallization surfaces. At block 110, a metallization seed layer is deposited. The seed layer may be deposited directly on a surface of the underlying package material(s) or upon a surface of an intervening adhesion material layer, if present. The seed layer may be predominantly copper, for example. The seed layer may be substantially pure or may be alloyed with one or more other metals and/or dopants. The seed layer may be deposited to any thickness that ensures sufficient conductivity for a subsequent deposition of a bulk metallization layer. The seed layer may be deposited by any technique known to be suitable. In accordance with some embodiments where a package insulator comprises an organic dielectric material that can decompose at higher temperatures (e.g., >400° C.), a PVD process or electroless deposition process is practiced at block 110.

Methods 100 continue at block 115 where one or more mask materials are applied over the seed layer. Openings are formed in the mask material, exposing a first portion of the seed layer where bulk metallization is to be formed. The mask material(s) may be entirely sacrificial, such as any photoresist that may be lithographically patterned. Alternatively, some of the mask material may instead be retained as a permanent package dielectric that is similarly photodefinable and generally known as a photoimagable dielectric (PID) material.

Methods 100 continue at block 120 where a bulk metallization layer is deposited in contact with the first portion of the seed layer exposed within the mask openings. In exemplary embodiments, the bulk metallization is advantageously predominantly Cu. In some embodiments, block 120 entails a Cu plating process, which may be either electroless or electrolytic. For electroless embodiments, the seed layer has a surface chemistry that will initiate the electroless deposition of the bulk metallization layer. For electrolytic embodiments, the seed layer is sufficiently conductive to support electrolytic plating of the bulk metallization layer. For either electroless or electrolytic plating embodiments, the bulk metallization layer is advantageously deposited to a thickness exceeding that of the seed layer. The bulk metallization layer may therefore represent the bulk of a line metallization feature to provide high electrical conductivity not possible with only the seed layer.

In exemplary embodiments, line metallization is formed at block 120 according to the openings formed at block 115. Blocks 115 and 120 may be iterated, for example with any multiple (e.g., double) patterning process to first form line metallization according to one mask pattern and further form via metallization over the line metallization according to another mask pattern. One or more masking materials may be deposited and patterned according to any techniques known to be suitable for multiple patterning semi-additive processing.

In the example further illustrated in FIG. 3, a seed layer 210 has been deposited upon package substrate 200. Mask material 305 is over a first portion of seed layer 210. A line metallization layer 310 is over a second portion of seed layer 210 exposed within openings of mask material 305 where lines or traces are desired. Line metallization layer 310 is advantageously predominantly copper. Line metallization layer 310 has a thickness T2, which is advantageously greater than a thickness of seed layer 210. In exemplary embodiments, thickness T2 is at least twice the thickness of seed layer 210, and may be for example 1 μm, or more. In some embodiments, thickness T2 is advantageously at least 2 μm, and may be as much as 3-15 μm.

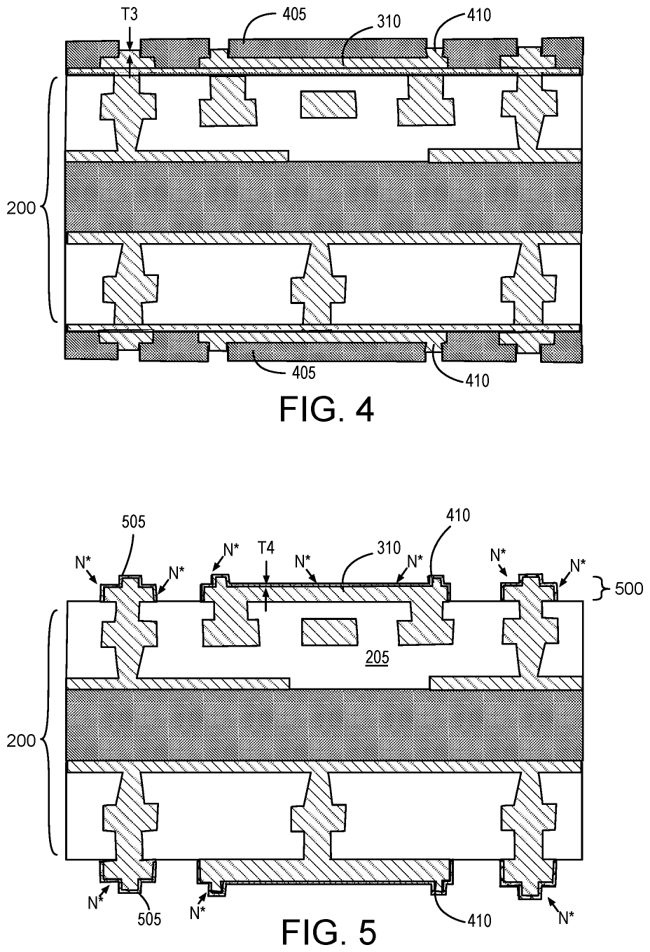

FIG. 4 further illustrates an example where another mask material 405 is over a portion of line metallization layer 310. Mask material 405 is illustrated as replacing mask material 305 (FIG. 3), but mask material 405 may instead supplement a previously applied mask material. A via metallization layer 410 is over a portion of line metallization layer 310 exposed within openings of mask material 405 where conductive vias are desired. In exemplary embodiments, via metallization layer 410 has substantially the same composition as line metallization layer 310 (e.g., predominantly copper). However, via metallization layer 410 may instead have a chemical composition distinct from that of line metallization layer 310. Via metallization layer 410 has a thickness T3, which is also advantageously greater than a thickness of seed layer 210. In exemplary embodiments, thickness T3 is, for example 1 μm, or more. In some embodiments, thickness T3 is advantageously at least 2 μm, and may as much as 3-15 μm.

Returning to FIG. 1, methods 100 continue at block 125 where at least some of the mask material is removed to expose a second portion of the seed layer. In these locations the seed layer is removed to complete delineation of line and via metallization features. Advantageously, the etch process does not significantly roughen surfaces of the line metallization and/or via metallization. At block 130, exposed surfaces of the metallization features are chemically treated with a species comprising nitrogen. The treatment is to introduce nitrogen to the exposed surfaces, and may incorporate nitrogen only onto a surface of the metallization features, or into a none-zero surface layer thickness. The nitrogen may advantageously react with one or more metals present at the surface of the metallization feature, forming a metal nitride compound. For example, in some embodiments where the metallization feature comprises predominantly copper, a copper nitride compound, such as Cu₃N, is formed on the exposed surfaces of the metallization features.

In some embodiments, block 130 comprises a plasma nitridation where a precursor gas comprising nitrogen is energized into a plasma, for example with an RF or microwave power source (e.g., generator, magnetron, etc.) In exemplary embodiments, the prescursor gas is NH₃. Other precursors, such as, but not limited to, N₂O or N₂ are also possible. The plasma processing of the packaging substrate may occur at any process parameters (e.g., partial pressures and a temperatures) with some examples comprising pressures in the tens to hundreds of mTorr range and temperatures in the 50-300° C. range. Such processing may be performed for any duration, with 10-60 seconds being one exemplary range.

In the example further illustrated in FIG. 5, a metal nitride layer 505 is illustrated on surfaces of features of metallization level 500 exposed to energized nitrogen species N*. In this example, the metal nitridation is performed on both sides of substrate 200. However, in other embodiments, nitridation is performed only one on side of the substrate (e.g., die-side). As shown, metal nitride layer 505 is formed both on a top surface and a sidewall surface of line metallization 310. Metal nitride layer 505 is also formed both on a top surface and a sidewall surface of via metallization 410. Although metal nitride layer 505 may only be on a surface of metallization features, nitride layer 505 may have a non-zero thickness T4 that is advantageously less than 1 μm to limit a reduction in the conductivity of the metallization features associated with the conversion of metal into metal nitride. Thickness T4, may, in some particularly advantageous examples, be less than 100 nm, and potentially as thin as 2-10 nm. Notably, metal nitride layer 505 need not be a continuous film and may instead be discontinuous, for example with pinholes and/or islands of nitride material that have not completely coalesced into a continuous film.

Metal nitride layer 505 comprises nitrogen and one or more metals that are present within line metallization 310 and via metallization 410. For an example where line metallization 310 and via metallization 410 are both predominantly Cu (e.g., substantially pure Cu), nitride layer 505 comprises predominantly Cu and nitrogen. Although the metal nitride may be a stoichiometric mixture (e.g., Cu₃N) where nitrogen content would be approximately 2×10²² atoms/cm³, the nitrogen content may also be substoichiometric. In some examples, nitrogen content within metal nitride layer 505 is at least 1e21 atoms/cm³. Nitrogen content rapidly declines with depth below the nitride surface layer thickness T4. In exemplary embodiments, nitrogen content within a bulk of line metallization 310 and via metallization 410 below nitride layer 505 is substantially nil (i.e., falling by 5-8 orders of magnitude to become undetectable).

In addition to nitrogen, metal nitride layer 505 may further comprise other constituents. These constituents may be substantially absent from the underlying bulk line metallization 310 and/or via metallization 410. In some examples, metal nitride layer 505 further comprises one or more dopant species, such as, but not limited to, atoms from Group IV of the periodic table, and/or atoms from Group III, and/or atoms from Group V other than nitrogen. In some specific examples, metal nitride layer 505 includes at least one of Si, Ge, Ga, or In. In still other embodiments, one or more rare earth elements may be present within metal nitride layer 505, but substantially absent from underlying bulk line metallization 310 and/or via metallization 410. In some examples, at least one of Hf, Sr, Ti or Va is present within metal nitride layer 505. Oxygen content within metal nitride layer 505 may also be higher than within underlying bulk line metallization 310 and/or via metallization 410.

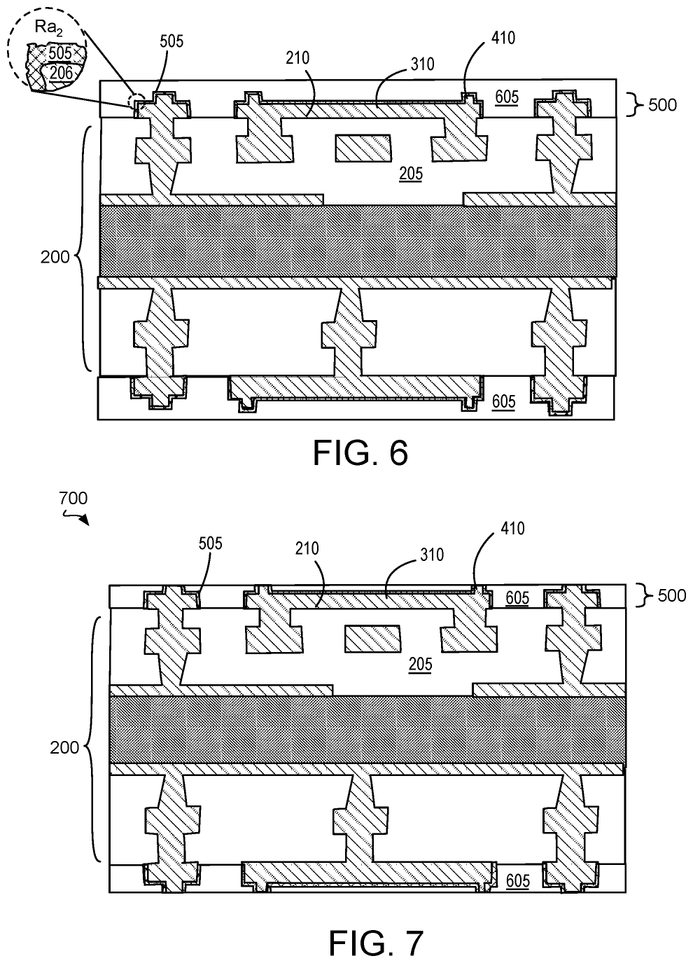

Following nitridation of the metallization feature surfaces, methods 100 (FIG. 1) continue at block 135 where a package insulator is formed over the metallization features. In exemplary embodiments, an organic dielectric material, such as any of the materials described above for dielectric materials within the package substrate, may be applied by liquid dispense followed by a curing process, or applied as a dry film laminate, for example. In the embodiment further illustrated in FIG. 6, an insulator 605 is over features of metallization level 500. Insulator 605 may be any of the organic dielectric materials described above for insulator 205, for example.

Adhesion of insulator 605 is improved by nitride layer 505, with greater chemical bonding occurring across the interface of the two materials because of the nitrogen incorporated into the metallization features. As further illustrated in the expand view inset of FIG. 6, the surface of nitride layer 505 may have an advantageously a low average surface roughness (e.g., Ra<100 nm, and more advantageously <50 nm). This smooth line metallization surface layer may convey data signals at higher frequencies with lower signal loss.

Returning to FIG. 1, methods 100 continue at block 140 where the package insulator formed at block 135 is planarized with a top surface of the metallization features. This planarization process may remove the metal nitride layer from a top surface of via metallization exposed by the planarization. Since metal nitride compounds can be significantly more electrically resistive than the pure metal, it is advantageous to remove the metal nitride from surfaces where another level of metallization will be formed. Accordingly, nitrogen may be incorporated only into metallization surfaces that provide the greatest benefit to adhesion while incurring the smallest penalty in electrical resistance.

Methods 100 then complete at output 190 where the IC device package metallization structure is completed, for example by forming one or more additional levels of metallization features over the features of the metallization level fabricated through one iteration of blocks 110-140. In some embodiments, any of the processes and materials described above may be deposited or otherwise applied to further build-up the package substrate in preparation for an assembly of one or more IC die, as further described below. Completing the package metallization structure may further entail performing another iteration of blocks 110-140 to form one or more additional metallization levels, and/or by performing one or more other methods to form one or more additional metallization levels. Downstream of output 190, a first side of the completed package metallization structure may be interconnected to any number of IC die while a second side of the completed package may be interconnected to any suitable host component.

In the exemplary IC device structure 700 further illustrated in FIG. 7, insulator 605 has been planarized with a surface via metallization layer 410. Both line metallization material layer 310 and metallization material layer 210 are therefore fully embedded within insulator 205 and/or insulator 605. As shown, metal nitride surface layer 505 remains only on a top surface and sidewall surface of line metallization 310, and on a sidewall surface of via metallization 410. A top surface of via metallization 410 is substantially free of nitrogen, and therefore ready to be further built up through the deposition of additional metallization.

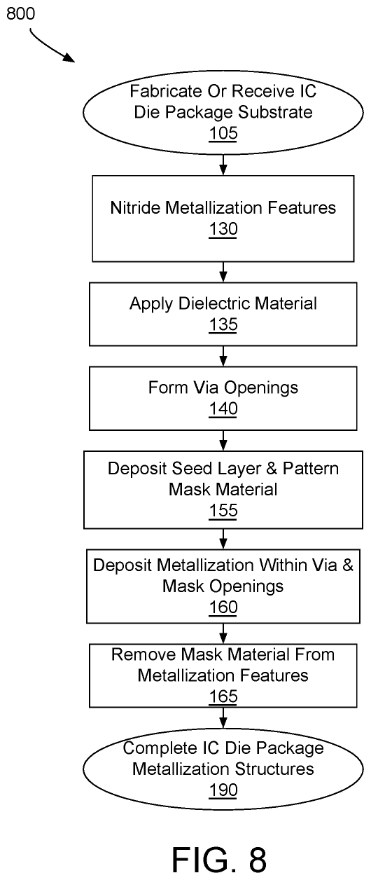

FIG. 8 is a flow diagram illustrating methods 800 for fabricating IC device package routing with metallization features comprising a metal nitride surface layer, in accordance with some alternative embodiments. Methods 800 are also SAP techniques that may be practiced to fabricate IC packages with an electrical routing structure including metallization features comprising a metal nitride surface layer.

In methods 800, one or more surfaces of metallization features within an IC device package are nitrided to improve the adhesion of one or more organic dielectric build-up materials applied over the metallization features as a package electrical insulator. The package line metallization structures fabricated according to methods 800 may therefore chemically enhance adhesion between the metallization and package insulator material(s) so that package line metallization need not be mechanically treated to avoid delamination of the package insulator. Because mechanical treatments generally rely to some extend on micro-roughening of the metallization feature surfaces, the chemical adhesion promoters described herein may induce less dimensional loss and can reduce the average roughness of the metallization features. Signals conveyed through the line metallization fabricated according to methods 800 may therefore experience reduced insertion losses.

Methods 800 may be repeated any number of times to build up an interconnect structure comprising any number of levels of metallization features comprising multiple material layers. FIGS. 8-13 further illustrate cross-sectional views through an IC device package as selected operations of one iteration of methods 800 are performed in accordance with some embodiments. In FIGS. 8-13 exemplary metallization structures are illustrated only on a “die-side” of the IC device package. However, two opposing sides of an IC device package may be concurrently built-up in a similar manner, for example like the double-sided embodiments illustrated in FIGS. 2-7.

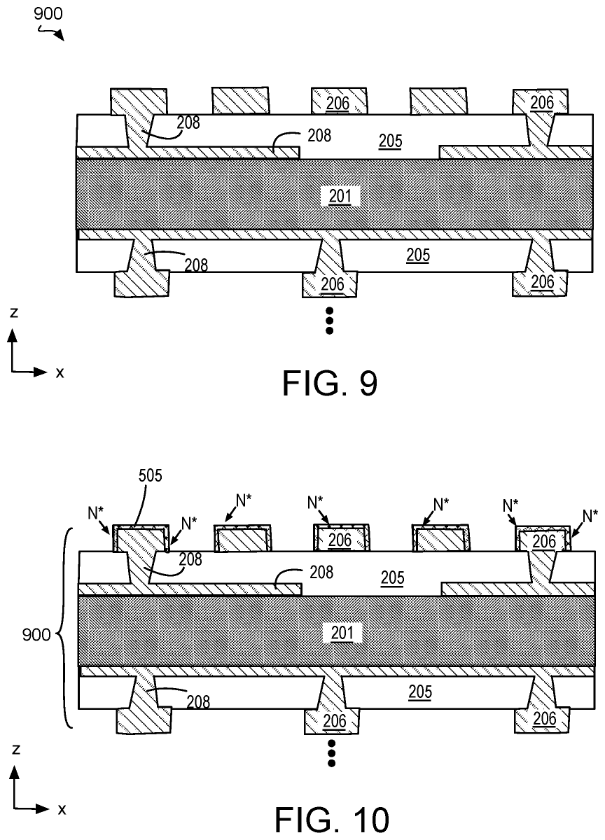

Methods 800 again begin an input 110 where an IC die package substrate is fabricated or received as a preform. Any of the cored or coreless package substrates described above as inputs to methods 100 (FIG. 1) may also be received as an input to methods 800 (FIG. 8). However, for methods 800 the package substrate received comprises non-planarized metallization features. For example, as shown in FIG. 9, package substrate 900 comprises a plurality of line metallization features 206 proud of a substantially planar surface of package insulator 205.

Returning to FIG. 8, methods 800 continue at block 130 where nitrogen is introduced to exposed surfaces of the line metallization features. Any of the surface treatments described above for block 130 in the context of methods 100 may be similarly practiced in the context of methods 800. For example, in the example further shown in FIG. 10, a plasma nitridation process has been performed to form metal nitride surface layer 505 upon surfaces of line metallization features 206. Nitride surface layer 505 may have any of the material properties, thicknesses, and/or compositions described above. In one example where line metallization features 206 are predominantly Cu, nitride surface layer is predominantly Cu and N.

Returning to FIG. 8, methods 800 continue at block 135 where package insulator is deposited. The package insulator may be, for example, any of the organic dielectric materials described above. Adhesion of the package insulator to the metal nitride surface layer formed at block 130 may be significantly improved relative to a metallization feature lacking such surface nitrogen. At block 140, via openings are formed through the package insulator to expose a portion of the underlying line metallization. Via openings may be formed with any process suitable for the package dielectric material. Depending on material composition, via openings within the package dielectric material may be mechanically drilled, laser ablated, or etched with a wet or dry (plasma) etch process. In exemplary embodiments, any nitride surface layer exposed at the bottom of the via opening is also removed as such a material layer may otherwise increase electrical resistance at the interface of via metallization and the underlying line metallization.

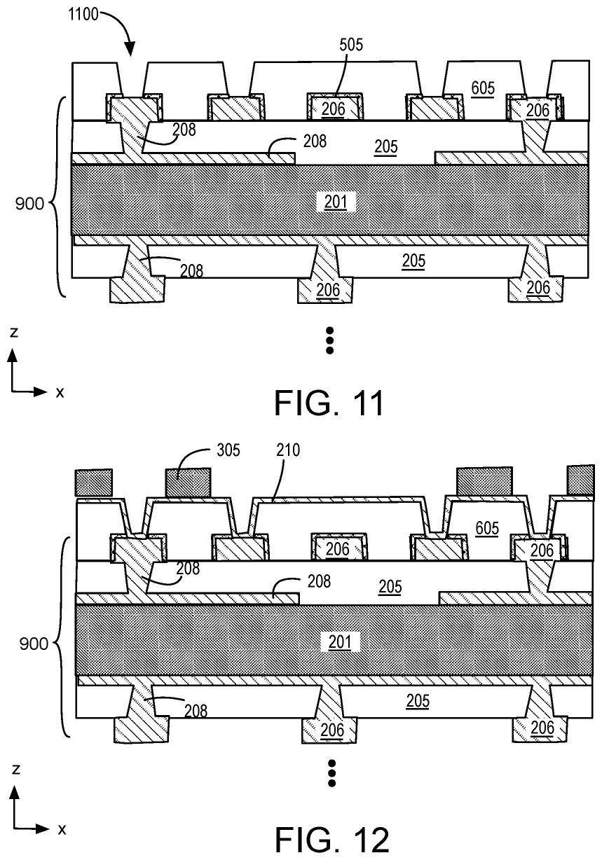

In the example further illustrated in FIG. 11, via openings 1100 have been formed through a thickness of package insulator 605, exposing a portion of line metallization features 206. The via opening process has cleared through a thickness of metal nitride surface layer 505. Accordingly, nitride surface layer 505 remains only on sidewall surfaces of line metallization 206 and on top surfaces of line metallization 206 beyond the perimeter of via openings 1100.

Returning to FIG. 8, methods 800 continue at block 155 where a seed metallization layer is deposited and a mask material is deposited over the seed layer. The mask material is patterned to define a next level of line metallization features. In the example further illustrated in FIG. 12, seed layer 210 is again illustrated to cover the entirety of the package substrate surface. Mask material 305 masks a portion of seed layer 210, thereby defining polygonal areas where the next level of line metallization is to form.

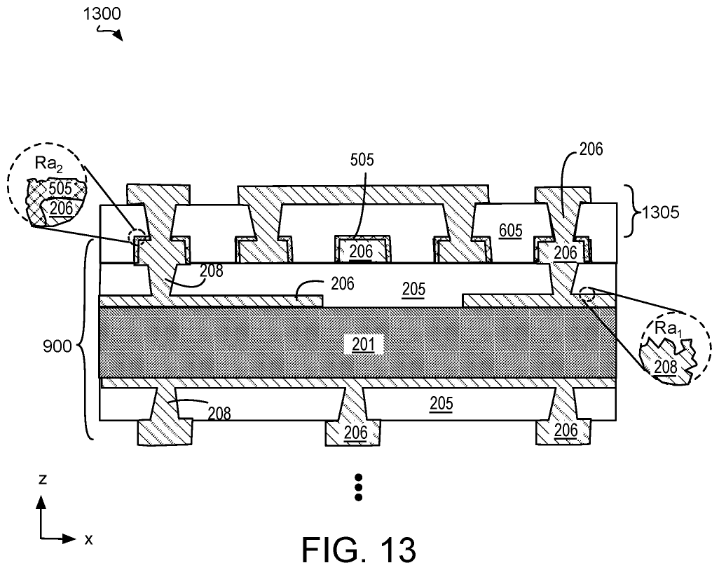

Methods 800 (FIG. 8) continue at block 160 where metallization is deposited within the via openings, and also deposited over unmasked regions of the package insulator. Any of suitable electroless or electrolytic plating process may be practiced at block 160. In some examples, a Cu electroplating process substantially fills the via openings with metallization comprising predominantly Cu. In the example further illustrated in FIG. 13, IC package substrate 1300 includes a metallization level 1305 over line metallization features 206. Accordingly, IC package substrate 1300 is ready for another iteration through methods 800 if an additional level of metallization is desired.

As shown in FIG. 13, metal nitride surface layer 505 may improve the adhesion of package insulator 605 to such an extent that the top surface of line metallization features 206 may have an average roughness Ra₂ that is much smaller than the average roughness Ra₁, which may be found elsewhere within package substrate 1300 (e.g., on a top surface of line metallization features 208, which lack a nitride surface layer.) Hence, various metallization levels within one IC device package may have different surface roughness as well as different surface compositions. In some embodiments, upper-level line metallization comprises a nitride surface layer for lowest high frequency signal transmission loss, while such a nitride surface layer is absent from lower-level line metallization for lowest electrical resistance. In contrast to package substrate 700, metal nitride surface layer 505 is only on surfaces of line metallization 206. Metal nitride surface layer 505 is substantially absent from via metallization 208, including a sidewall surface of via metallization 208. Hence, methods 800 may further limit the extend of metal nitride surface layer 505 to surfaces of line metallization that may most improve the adhesion of insulator 605 with a minimal electrical resistance penalty.

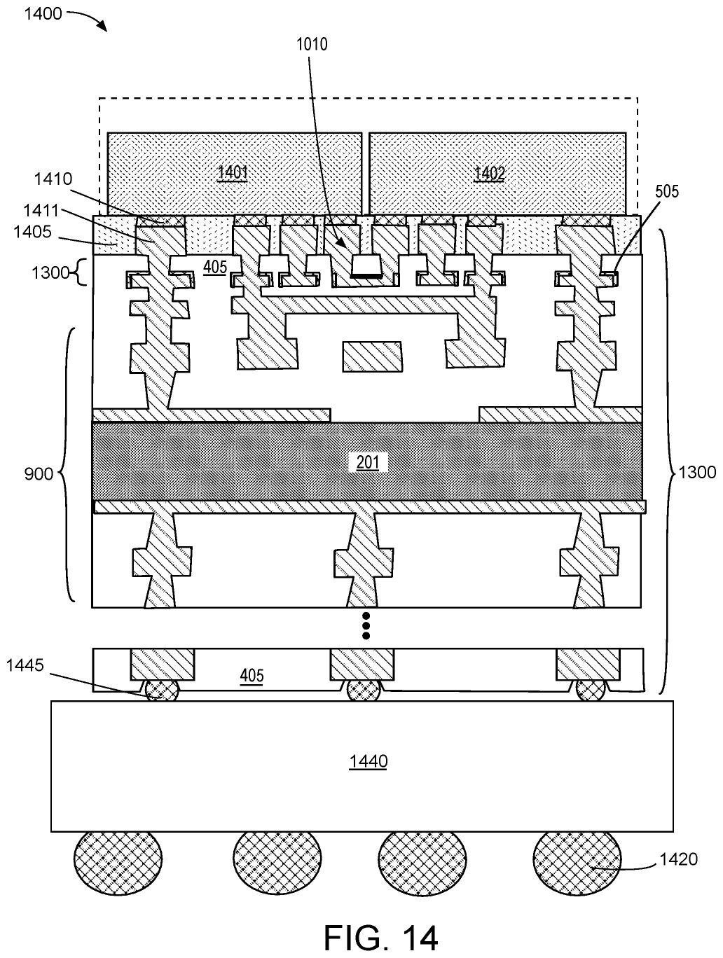

FIG. 14 illustrates a system 1400 including IC device package 1300 interconnecting two IC die 1401 and 1402 (chips or chiplets) to each other, in accordance with some embodiments. System 1400 may similarly include IC device package 700. In exemplary embodiments, at least IC die 1401 includes microprocessor circuitry, graphics processing circuitry, or heterogeneous processing circuitry. Microprocessor circuitry may be operable, for example, to execute a real-time operative system (RTOS). In some further embodiments, at least IC die 1401 is operable to execute one or more layers of a software stack that controls radio (wireless) functions. In some further embodiments, at least IC die 1402 includes electronic memory circuitry, such as, but not limited to, dynamic random-access memory (DRAM). In other embodiments, both of IC die 1401 and 1402 include memory circuitry, or both of IC die 1401 and 1402 include microprocessor circuitry.

In the example depicted in FIG. 14, IC die 1401 and 1402 are each attached to package metallization. In some examples, package interconnects 1411 are coupled to IC die interconnects 1410, which may comprise solder features, for example, or may be substantially solderless. IC die interconnect 1411 may comprise one or more layer of metallization that may, for example, include gold and/or nickel that makes direct contact with package interconnects 1410.

Notably, package metallization features interconnect IC die 1401 to the adjacent IC die 1402 as the smooth surfaces of line metallization satisfies the transmission requirements for high density interconnects between the multiple IC die assembled to the package metallization structure. Lower levels of metallization within IC die package 1300 lacking nitride surface layers may suffice for the delivery of power to IC dies 1401 and 1402.

As further illustrated in FIG. 14, a package dielectric 1405 is between package 1300 and IC dies 1401, 1402. Package dielectric 1405 may have substantially the same composition as insulator 405, for example, or package dielectric 1405 may have a different composition. In some embodiments, package dielectric 1405 is a mold or capillary underfill compound. In the illustrated example, package dielectric 1405 fills spaces between package interconnects 1411.

Host component 1440 may be a PCB or interposer attached to the package metallization through any suitable interconnect 1445. In some exemplary embodiments, a land-side of host component 1440 opposite IC dies 1401, 1402 is further processed to receive second level interconnects 1420. System 1400 may further include one or more of overmold, a heat spreader, and/or active cooling structure 1450.

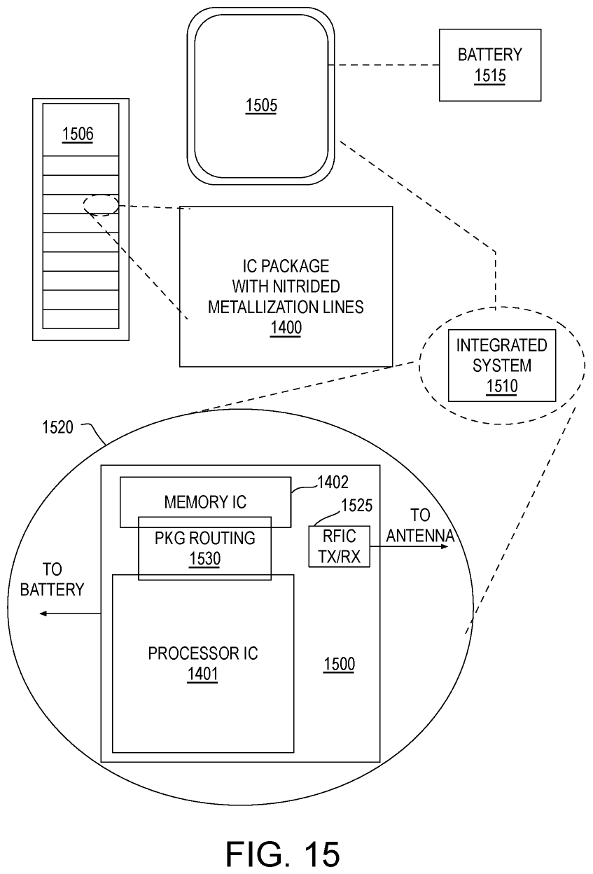

FIG. 15 illustrates a mobile computing platform and a data server machine employing package routing with a nitride surface layer, for example as described elsewhere herein. The server machine 1506 may be any commercial server, for example including any number of high-performance computing platforms disposed within a rack and networked together for electronic data processing, which in the exemplary embodiment includes a packaged monolithic SoC. The mobile computing platform 1505 may be any portable device configured for each of electronic data display, electronic data processing, wireless electronic data transmission, or the like. For example, the mobile computing platform 1505 may be any of a tablet, a smart phone, laptop computer, etc., and may include a display screen (e.g., a capacitive, inductive, resistive, or optical touchscreen), a chip-level or package-level integrated system 1510, and a battery 1515.

As a system component within the server machine 1506, a memory IC (e.g., RAM) die 1402 and a processor IC (e.g., a microprocessor, a multi-core microprocessor, baseband processor, or the like) die 1401 are interconnected through a package routing 1530 that further includes a nitride surface layer, for example substantially as described elsewhere herein. One or more other IC die may also be assembled with package 1500. For example, a RF (wireless) integrated circuit (RFIC) 1525 including a wideband RF (wireless) transmitter and/or receiver (TX/RX) may be further interconnected to package 1500. Functionally, RFIC 1525 may have an output coupled to an antenna to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

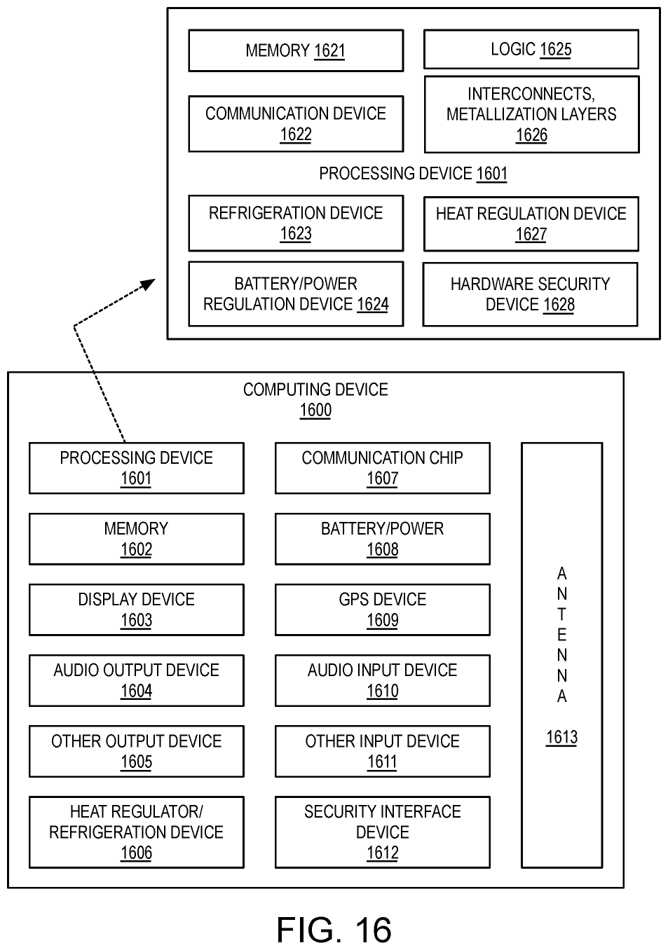

FIG. 16 is a block diagram of a cryogenically cooled computing device 1600 in accordance with some embodiments. For example, one or more components of computing device 1600 may include any of the devices or structures discussed elsewhere herein. A number of components are illustrated in FIG. 16 as included in computing device 1600, but any one or more of these components may be omitted or duplicated, as suitable for the application. In some embodiments, some or all of the components included in computing device 1600 may be attached to one or more printed circuit boards (e.g., a motherboard). In some embodiments, various ones of these components may be fabricated onto a single system-on-a-chip (SoC) die. Additionally, in various embodiments, computing device 1600 may not include one or more of the components illustrated in FIG. 16, but computing device 1600 may include interface circuitry for coupling to the one or more components. For example, computing device 1600 may not include a display device 1603, but may include display device interface circuitry (e.g., a connector and driver circuitry) to which display device 1603 may be coupled.

Computing device 1600 may include a processing device 1601 (e.g., one or more processing devices). As used herein, the term processing device or processor indicates a device that processes electronic data from registers and/or memory to transform that electronic data into other electronic data that may be stored in registers and/or memory. Processing device 1601 may include a memory 1621, a communication device 1622, a refrigeration/active cooling device 1623, a battery/power regulation device 1624, logic 1325, interconnects 1626, a heat regulation device 1627, and a hardware security device 1628.

Processing device 1601 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1601 may include a memory 1602, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing 1601 shares a package with memory 1602. This memory may be used as cache memory and may include embedded dynamic random-access memory (eDRAM) or spin transfer torque magnetic random-access memory (STT-M RAM).

Computing device 1600 may include a heat regulation/refrigeration device 1623. Heat regulation/refrigeration device 1623 may maintain processing device 1601 (and/or other components of computing device 1600) at a predetermined low temperature during operation. This predetermined low temperature may be any temperature discussed elsewhere herein.

In some embodiments, computing device 1600 may include a communication chip 1607 (e.g., one or more communication chips). For example, the communication chip 1607 may be configured for managing wireless communications for the transfer of data to and from computing device 1600. The term “wireless” and its derivatives may be used to describe circuits, devices, systems, methods, techniques, communications channels, etc., that may communicate data through the use of modulated electromagnetic radiation through a nonsolid medium.

Communication chip 1607 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1307 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1307 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1607 may operate in accordance with other wireless protocols in other embodiments. Computing device 1600 may include an antenna 1613 to facilitate wireless communications and/or to receive other wireless communications (such as AM or FM radio transmissions).

In some embodiments, communication chip 1607 may manage wired communications, such as electrical, optical, or any other suitable communication protocols (e.g., the Ethernet). As noted above, communication chip 1607 may include multiple communication chips. For instance, a first communication chip 1607 may be dedicated to shorter-range wireless communications such as Wi-Fi or Bluetooth, and a second communication chip 1607 may be dedicated to longer-range wireless communications such as GPS, EDGE, GPRS, CDMA, WiMAX, LTE, EV-DO, or others. In some embodiments, a first communication chip 1607 may be dedicated to wireless communications, and a second communication chip 1607 may be dedicated to wired communications.

Computing device 1600 may include battery/power circuitry 1608. Battery/power circuitry 1608 may include one or more energy storage devices (e.g., batteries or capacitors) and/or circuitry for coupling components of computing device 1300 to an energy source separate from computing device 1600 (e.g., AC line power).

Computing device 1600 may include a display device 1603 (or corresponding interface circuitry, as discussed above). Display device 1603 may include any visual indicators, such as a heads-up display, a computer monitor, a projector, a touchscreen display, a liquid crystal display (LCD), a light-emitting diode display, or a flat panel display, for example.

Computing device 1600 may include an audio output device 1604 (or corresponding interface circuitry, as discussed above). Audio output device 1604 may include any device that generates an audible indicator, such as speakers, headsets, or earbuds, for example.

Computing device 1600 may include an audio input device 1610 (or corresponding interface circuitry, as discussed above). Audio input device 1610 may include any device that generates a signal representative of a sound, such as microphones, microphone arrays, or digital instruments (e.g., instruments having a musical instrument digital interface (MIDI) output).

Computing device 1600 may include a global positioning system (GPS) device 1609 (or corresponding interface circuitry, as discussed above). GPS device 1609 may be in communication with a satellite-based system and may receive a location of computing device 1600, as known in the art.

Computing device 1600 may include another output device 1605 (or corresponding interface circuitry, as discussed above). Examples include an audio codec, a video codec, a printer, a wired or wireless transmitter for providing information to other devices, or an additional storage device.

Computing device 1600 may include another input device 1611 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1600 may include a security interface device 1612. Security interface device 1612 may include any device that provides security measures for computing device 1600 such as intrusion detection, biometric validation, security encode or decode, managing access lists, malware detection, or spyware detection.

Computing device 1600, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In first examples an integrated circuit (IC) device package comprises a substrate comprising a dielectric material, and one or more metallization lines extending over the dielectric material, wherein the metallization lines comprise Cu and N.

In second examples, for any of the first examples the metallization lines comprise predominantly Cu and wherein the N has a first concentration proximal to a sidewall surface of the lines that is higher than a second concentration within an interior of the metallization line, distal from the sidewall surface.

In third examples, for any of the first through second examples the first concentration is at least 1e21 atoms/cm³.

In forth examples, for any of the first through third examples the metallization lines comprise a surface layer of predominantly Cu and N and a bulk under the surface layer, the bulk comprising predominantly Cu and having less N than the surface layer.

In fifth examples, for any of the fourth examples the surface layer is on top of the metallization lines, between the bulk and an insulator material over the metallization lines.

In sixth examples, for any of the first through fourth examples the surface layer has a thickness of 2 nm-1 μm.

In seventh examples for any of the sixth examples the surface layer has a thickness less than 100 nm.

In eighth examples, for any of the fourth through seventh examples the package comprises one or more metallization vias in direct contact with the metallization lines, wherein the metallization vias also comprise the surface layer of predominantly Cu and N.

In ninth examples, for any of the eighth examples the surface layer defines a sidewall of the metallization vias, and the surface layer is in direct contact with an insulator material.

In tenth examples, for any of the first through seventh examples the IC package comprises one or more metallization vias in direct contact with the metallization lines, wherein the surface layer is substantially absent from a sidewall of the metallization vias.

In eleventh examples, for any of the fourth through tenth examples the bulk has a thickness of at least 3 μm.

In twelfth examples, for any of the first through eleventh examples the one or more metallization lines comprise a first metallization line, the first metallization line comprises a surface layer of predominantly Cu and N and a bulk under the surface layer, the bulk comprising predominantly Cu and having less N than the surface layer, the substrate further comprises a second metallization line under the dielectric material, and the surface layer is absent from the second metallization line.

In thirteenth examples, for any of the twelfth examples a top surface of the second metallization line has a higher average roughness than a top surface of the first metallization line.

In fourteenth examples, for any of the thirteenth examples the top surface of the second metallization line has an average roughness exceeding 200 nm, and wherein the top surface of the first metallization line has an average roughness below 100 nm.

In fifteenth examples, a system comprises a first integrated circuit (IC) die, a second IC die, and an integrated circuit (IC) device package. The package comprises a metallization line interconnecting the first IC die to the second IC die. The metallization line comprises predominantly Cu, and a first amount of N proximal to a sidewall surface of the line that is greater than a second amount of N within an interior of the metallization line, distal from the sidewall surface.

In sixteenth examples, for any of the fifteenth examples the first and second IC die are over a first side of the IC device package, and wherein a second side of the IC device package is coupled to a host component, and the system further comprises a power supply coupled to the IC device package through an interconnect interface between the IC device package and the host component.

In seventeenth examples, a method of fabricating an integrated circuit (IC) device package comprises receiving a substrate comprising a dielectric material, forming a metallization feature over the dielectric material, introducing nitrogen into the metallization feature, and depositing additional dielectric material over the metallization feature.

In eighteenth examples, for any of the seventeenth examples forming the metallization feature comprises electrolytically or electrolessly plating Cu, and introducing nitrogen into the metallization feature comprises exposing the Cu to a plasma generated from a precursor gas comprising nitrogen.

In nineteenth examples, for any of the eighteenth examples the precursor gas comprises at least one of NH₃, N₂O, N₂.

In twentieth examples, for any of the seventeenth through nineteenth examples introducing nitrogen into the metallization feature forms a surface layer comprising nitrogen and that has a thickness less than 100 nm, and wherein below the surface layer, the metallization is substantially free of nitrogen.

It will be recognized that principles of the disclosure are not limited to the embodiments so described, but instead can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An integrated circuit (IC) device package, comprising:
a substrate comprising a dielectric material; and
one or more metallization lines extending over the dielectric material, wherein the metallization lines comprise Cu and N.

2. The IC device package of claim 1, wherein the metallization lines comprise predominantly Cu and wherein the N has a first concentration proximal to a sidewall surface of the lines that is higher than a second concentration within an interior of the metallization line, distal from the sidewall surface.

3. The IC device package of claim 2, wherein the first concentration is at least 1e21 atoms/cm³.

4. The IC device package of claim 1, wherein the metallization lines comprise a surface layer of predominantly Cu and N and a bulk under the surface layer, the bulk comprising predominantly Cu and having less N than the surface layer.

5. The IC device package of claim 4, wherein the surface layer is on top of the metallization lines, between the bulk and an insulator material over the metallization lines.

6. The IC device package of claim 4, wherein the surface layer has a thickness of 2 nm-1 μm.

7. The IC device package of claim 6, wherein the surface layer has a thickness less than 100 nm.

8. The IC device package of claim 4, further comprises one or more metallization vias in direct contact with the metallization lines, wherein the metallization vias also comprise the surface layer of predominantly Cu and N.

9. The IC device package of claim 8, wherein the surface layer defines a sidewall of the metallization vias, and the surface layer is in direct contact with an insulator material.

10. The IC device package of claim 4, further comprising one or more metallization vias in direct contact with the metallization lines, wherein the surface layer is substantially absent from a sidewall of the metallization vias.

11. The IC device package of claim 4, wherein the bulk has a thickness of at least 3 μm.

12. The IC device package of claim 1, wherein:
the one or more metallization lines comprise a first metallization line;
the first metallization line comprises a surface layer of predominantly Cu and N and a bulk under the surface layer, the bulk comprising predominantly Cu and having less N than the surface layer;
the substrate further comprises a second metallization line under the dielectric material; and
the surface layer is absent from the second metallization line.

13. The IC device package of claim 12, wherein a top surface of the second metallization line has a higher average roughness than a top surface of the first metallization line.

14. The IC device package of claim 13, wherein the top surface of the second metallization line has an average roughness exceeding 200 nm, and wherein the top surface of the first metallization line has an average roughness below 100 nm.

15. A system comprising:
a first integrated circuit (IC) die;
a second IC die; and
an integrated circuit (IC) device package, comprising:
a metallization line interconnecting the first IC die to the second IC die, wherein the metallization line comprises predominantly Cu, and a first amount of N proximal to a sidewall surface of the line that is greater than a second amount of N within an interior of the metallization line, distal from the sidewall surface.

16. The system of claim 15, wherein:
the first and second IC die are over a first side of the IC device package, and wherein a second side of the IC device package is coupled to a host component; and
the system further comprises a power supply coupled to the IC device package through an interconnect interface between the IC device package and the host component.

17. A method of fabricating an integrated circuit (IC) device package, the method comprising:
receiving a substrate comprising a dielectric material;
forming a metallization feature over the dielectric material;
introducing nitrogen into the metallization feature; and
depositing additional dielectric material over the metallization feature.

18. The method of claim 17, wherein:
forming the metallization feature comprises electrolytically or electrolessly plating Cu; and
introducing nitrogen into the metallization feature comprises exposing the Cu to a plasma generated from a precursor gas comprising nitrogen.

19. The method of claim 17, wherein the precursor gas comprises at least one of NH₃, N₂O, N₂.

20. The method of claim 17, wherein introducing nitrogen into the metallization feature forms a surface layer comprising nitrogen and that has a thickness less than 100 nm, and wherein below the surface layer, the metallization is substantially free of nitrogen.
